(19) United States
(12) Patent Application Publication
(10) Pub. No.: US 2025/0022644 A1
(43) Pub. Date: Jan. 16, 2025

(54) MAGNETIC FIELD GENERATION SYSTEM

(71) Applicant: HPROBE, EYBENS (FR)

(72) Inventors: Gilles ZAHND, EYBENS (FR); Antoine CHAVENT, EYBENS (FR); Siamak SALIMY, EYBENS (FR)

(21) Appl. No.: 18/714,419

(22) PCT Filed: Dec. 5, 2022
(86) PCT No.: PCT/EP2022/084456

§ 371 Date: May 29, 2024

(30) Foreign Application Priority Data
Dec. 7, 2021 (FR) 21/13055

(51) Int. Cl. H01F 7/20; G01R 33/00

(52) U.S. Cl. CPC H01F 7/204; G01R 33/0005

(57) ABSTRACT

The present description concerns a magnetic field generation system (200) comprising:
a central pole (220) arranged above a plane (XY), the axis of said central pole extending along a direction orthogonal to the plane;
at least two planar poles (216A, 216B, 216C, 216D) arranged symmetrically on the plane with respect to the axis of the central pole; and
at least two coils (230A, 230B, 230C, 230D), including at least one coil associated with each planar pole;
   two coils associated with two different planar poles being adapted to being connected to two distinct power supply circuits; each power supply circuit being adapted to conducting, in at least one coil to which it is connected, a current having an intensity and a direction determined according to a desired magnetic field and to the orientation in the plane of the planar pole associated with said coil.

The present application is based on, and claims priority from, French patent application 2113055, filed on Dec. 7, 2021, entitled “Systéme de generation de champ magnétique”, which is incorporated by reference to the extent permitted by law.

### TECHNICAL BACKGROUND

The present disclosure concerns the field of magnetic field generators, and in particular a system adapted to generating a magnetic field of high amplitude.

### PRIOR ART

In certain technical fields, for example, for the electric testing of an integrated circuit wafer component under a magnetic field, particularly of a memory cell of a wafer, the application of a magnetic field at the level of the component is desired.

In certain cases, for the electric testing of a specific wafer component, for example a spintronic component or a cell of a magnetic random access memory (MRAM), the application of a magnetic field of high amplitude, typically greater than or equal to 0.5 T, and this, in a plurality of directions, may be desired. A magnetic field generator capable of generating a magnetic field of high amplitude in a plurality of directions is thus desired.

### SUMMARY OF THE INVENTION

There exists a need to improve magnetic field generation techniques.

In particular, there is a need to improve magnetic field generation techniques for the electric testing of an integrated circuit wafer component.

An embodiment overcomes all or part of the disadvantages of known magnetic field generators.

An embodiment provides a magnetic field generation system comprising a magnetic circuit comprising:
a central pole arranged above a plane, the axis of said central pole extending along an orthogonal direction substantially corresponding to the direction orthogonal to the plane;
at least two planar poles arranged symmetrically on the plane with respect to the axis of the central pole, each planar pole being supported by a portion of the magnetic circuit; and
at least two coils, including at least one coil associated with each planar pole, each coil associated with a planar pole surrounding the magnetic circuit portion supporting said planar pole;
   two coils associated with two different planar poles being adapted to being connected to two distinct power supply circuits; each power supply circuit being adapted to circulating, through at least one coil to which it is connected, a current having an intensity and a direction determined according to a desired magnetic field and to the orientation in the plane of the planar pole associated with said coil.

According to an embodiment, the system further comprises a processing unit adapted to determining the current to be circulated through each coil.

According to an embodiment, the processing unit is adapted to determining an equivalent current, for example represented in the form of an equivalent current vector, for the desired magnetic field, and to determining the current to be circulated through each coil according to the determined equivalent current and to the orientation in the plane of the planar pole associated with said coil. In other words, the intensity and the direction of the current in each coil are determined according to the geometry of the magnetic circuit, and according to the determined equivalent current. For example, the desired magnetic field is in the form of a magnetic field vector.

According to an embodiment, the system comprises three coils and three planar poles arranged symmetrically on the plane with respect to the axis of the central pole and being oriented by a first angle of approximately 120° with respect to one another.

According to a specific embodiment, the currents to be circulated through the three coils are respectively:

$${I}_{1} = {Ieq}_{X} + {Ieq}_{Z}$$

for a first coil associated with a first planar pole oriented toward the axis of the central pole towards the positive side of a first direction of the plane;

$${I}_{2} = - \frac{1}{2} {Ieq}_{X} + \frac{\sqrt{3}}{2} {Ieq}_{Y} + {Ieq}_{Z}$$

for a second coil associated with a second planar pole oriented by the first angle in the plane with respect to the first planar pole; and

$${I}_{3} = - \frac{1}{2} {Ieq}_{X} + \frac{\sqrt{3}}{2} {Ieq}_{Y} + {Ieq}_{Z}$$

for a third coil associated with a third planar pole oriented by the first angle in the plane with respect to the second planar pole;
where Ieq_{X}, Ieq_{Y}, Ieq_{Z} are the vector components representing the equivalent current Ieq respectively along the first direction, the second direction perpendicular to the first direction in the plane, and the orthogonal direction.

According to an embodiment, the system comprises four coils and four planar poles symmetrical with respect to two orthogonal planes containing the axis of the central pole, two adjacent planar poles being oriented by a second angle of approximately 90° with respect to each other.

According to a specific embodiment, the currents to be circulated through the four coils are respectively:

$${I}_{1} = {Ieq}_{X} + {Ieq}_{Y} + {Ieq}_{Z}$$

for a first coil associated with a first planar pole oriented towards the axis of the central pole at approximately 45° between first and second orthogonal directions in the plane, towards the positive side of said first and second directions;

$${I}_{2} = - {Ieq}_{X} + {Ieq}_{Y} + {Ieq}_{Z}$$

for a second coil associated with a second planar pole oriented by the second angle in the plane with respect to the first planar pole;

$${I}_{3} = - {Ieq}_{X} - {Ieq}_{Y} + {Ieq}_{Z}$$

for a third coil associated with a third planar pole oriented by the second angle in the plane with respect to the second planar pole; and

$${I}_{4} = {Ieq}_{X} - {Ieq}_{Y} + {Ieq}_{Z}$$

for a fourth coil associated with a fourth planar pole oriented by the second angle in the plane with respect to the third planar pole;
where I_{X}, I_{Y}, I_{Z} are the vector components representing the equivalent current Ieq respectively along the first direction, the second direction and the orthogonal direction.

According to an embodiment, the central pole is surrounded with a fifth coil adapted to being connected to a distinct power supply circuit of the coils associated with the planar poles and adapted to circulating through said fifth coil a current having an intensity and a direction determined according to the desired magnetic field and to the orientation of the central pole, for example, a current: I₅=Ieq_{Z} where Ieq_{Z} is the vector component representing the equivalent current along the orthogonal direction.

According to an embodiment, each pole corresponds to a first end of an arm, the arms being coupled to a frame.

According to an embodiment, each arm associated with a planar pole extends substantially in a direction parallel to the plane, a second end of said arm being assembled to a bar running inside of the at least one coil associated with said planar pole, each bar substantially extending in the orthogonal direction.

According to an embodiment, the arm associated with the central pole is assembled with a horizontal rod coupled to two opposite sides of the frame.

According to an embodiment, the coils have outer diameters greater than 70 mm, or even greater than 80 mm, for example, greater than or equal to 90 mm.

An embodiment provides a magnetic field generation method implementing a system comprising a magnetic circuit comprising:
a central pole arranged above a plane, the axis of said central pole extending along an orthogonal direction substantially corresponding to the direction orthogonal to the plane;
at least two planar poles arranged symmetrically on the plane with respect to the axis of the central pole, each planar pole being supported by a portion of the magnetic circuit; and
at least two coils, including at least one coil associated with each planar pole, each coil associated with a planar pole surrounding the magnetic circuit portion supporting said planar pole; two coils associated with two different planar poles being connected to two distinct power supply circuits;
   the method comprising:
circulating, through at least one coil connected to each power supply circuit, a current having an intensity and a direction determined according to a desired magnetic field and to the orientation in the plane of the planar pole associated with said coil.

According to an embodiment, the method comprises:
determining an equivalent current, for example in the form of an equivalent current vector, according to the desired magnetic field; and
determining the current to be circulated through each coil according to the determined equivalent current and to the orientation in the plane of the planar pole associated with said coil.

According to an embodiment, the method further comprises:
measuring the magnetic field obtained when the determined current flows through each coil;
comparing the measured magnetic field with the desired magnetic field; and, if the difference is greater than a defined threshold,
determining a second equivalent current according to the difference between the measured magnetic field and the desired magnetic field;
determining the current to be circulated through each coil according to the determined second equivalent current and to the orientation in the plane of the planar pole associated with said coil; and
repeating at least the magnetic field measurement and comparison steps, and, for example, also repeating the steps of determination of the second equivalent current and of the current to be circulated.

According to a specific embodiment, the system comprises three coils and three planar poles arranged symmetrically on the plane with respect to the axis of the central pole and being oriented by a first angle of approximately 120° with respect to each other; the method comprising:
circulating through a first coil associated with a first planar pole oriented towards the axis of the central pole towards the positive side of a first direction of the plane a current of intensity:

$${I}_{1} = {Ieq}_{X} + {Ieq}_{Z} ;$$

circulating through a second coil associated with a second planar pole oriented by the first angle in the plane with respect to the first planar pole a current of intensity:

$${I}_{2} = - \frac{1}{2} {Ieq}_{X} + \frac{\sqrt{3}}{2} {Ieq}_{Y} + {Ieq}_{Z} ;$$

and
circulating through a third coil associated with a third planar pole oriented by the first angle in the plane with respect to the second planar pole a current of intensity:

$${I}_{3} = - \frac{1}{2} {Ieq}_{X} - \frac{\sqrt{3}}{2} {Ieq}_{Y} + {Ieq}_{Z} ;$$

where Ieq_{X}, Ieq_{Y}, Ieq_{Z} are the vector components representing the equivalent current Ieq respectively along the first horizontal direction, the second direction perpendicular to the first direction in the plane, and the orthogonal direction.

According to a specific embodiment, the system comprises four coils and four planar poles symmetrical with respect to two orthogonal planes containing the axis of the central pole, two adjacent planar poles being substantially oriented by a second angle of approximately 90° with respect to each other; the method comprising:
circulating through a first coil associated with a first planar pole oriented towards the axis of the central pole at approximately 45° between first and second directions orthogonal in the plane, towards the positive side of said first and second directions, a current of intensity:

$${I}_{1} = {Ieq}_{X} + {Ieq}_{Y} + {Ieq}_{Z} ;$$

circulating through a second coil associated with a second planar pole oriented by the second angle in the plane with respect to the first planar a current of intensity:

$${I}_{2} = - {Ieq}_{X} + {Ieq}_{Y} + {Ieq}_{Z} ;$$

circulating through a third coil associated with a third planar pole oriented by the second angle in the plane with respect to the second planar a current of intensity:

$${I}_{3} = - {Ieq}_{X} - {Ieq}_{Y} + {Ieq}_{Z} ;$$

circulating through a fourth coil associated with a fourth planar pole oriented by the second angle in the plane with respect to the third planar a current of intensity:

$${I}_{4} = {Ieq}_{X} - {Ieq}_{Y} + {Ieq}_{Z} ;$$

where Ieq_{X}, Ieq_{Y}, Ieq_{Z} are the vector components representing the equivalent current Ieq respectively along the first direction, the second direction, and the orthogonal direction.

According to an embodiment, the desired determined equivalent current vector and magnetic field are dynamic.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A is a first perspective view of an example of a magnetic field generator;

FIG. 1B is a second perspective view of the magnetic field generator of the system of FIG. 1A;

FIG. 2A is a perspective view of a magnetic field generation system according to an embodiment;

FIG. 2B is a simplified transverse cross-section of the system of FIG. 2A;

FIG. 3A is a simplified perspective view of a magnetic field generation system according to another embodiment;

FIG. 3B is a simplified transverse cross-section of the system of FIG. 3A; and

FIG. 4 is a simplified transverse cross-section of a magnetic field generation system according to another embodiment.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the coil power supply circuits are not shown, and may be conductors coupled on the one hand to the coil to be powered, and on the other hand to a current generator provided with or coupled to a current regulator.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Unless specified otherwise, the angle values are given in the counterclockwise direction. For example, an angle value of 45°, of 90°, or of 120° should be understood as respectively being +45°, +90°, or +120° in the counterclockwise direction.

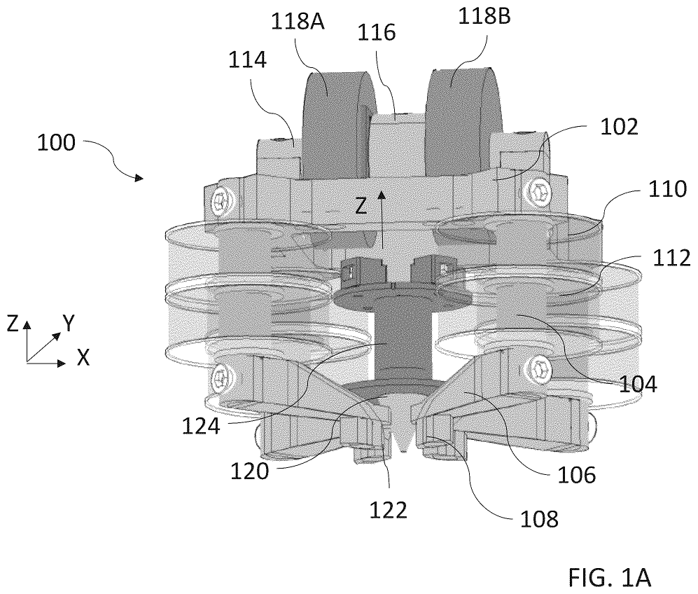

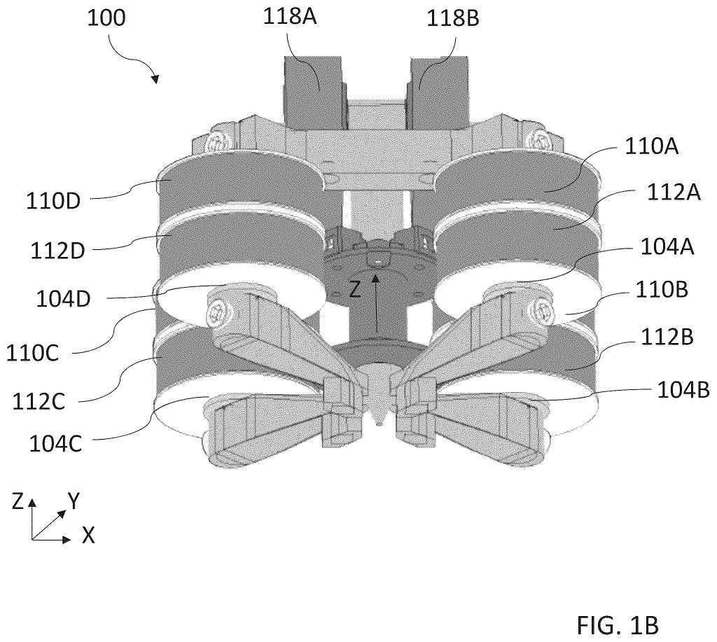

An example of magnetic field generator 100 is shown in FIG. 1A. It comprises a magnetic circuit comprising a substantially square frame 102 having its axis (central axis) extending along a vertical direction Z, and vertical bars 104 extending downwards from each corner of the frame. Each vertical bar is continued towards the central axis by a radial arm 106 ending in a polar end 108 (planar pole). Each vertical bar is surrounded with two coils 110, 112 (shown in transparency in FIG. 1A to be able to view the vertical bars). Two other coils 118A, 118B are arranged around a horizontal rod 114 on either side of a connecting block 116 located in the middle of rod 114. Horizontal rod 114 is attached to two opposite sides of frame 102. Connecting block 116 is continued by a vertical arm 120 having a cone-shaped polar end 122 (central pole). The central pole may be surrounded by a coil 124.

The coils are connected to power supply circuits, not shown.

There have been more precisely shown in FIG. 1B all the coils around the vertical bars: a first upper coil 110A and a second lower coil 112A around a first vertical bar 104A, a second upper coil 110B, and a second lower coil 112B around a second vertical bar 104B, a third upper coil 110C, and a third lower coil 112C around a third vertical bar 104C, a fourth upper coil 110D, and a fourth lower coil 112D around a fourth vertical bar 104D.

The coils 118A, 118B arranged around horizontal rod 114 may be powered within a same power supply network (power supply of the field in the Z direction) to generate respective magnetic induction fluxes which, either diverge from the Z axis, which results in a upward magnetic flux in vertical arm 120, or are directed towards the Z axis, which results in a downward flux in vertical arm 120. In both cases, this aims at obtaining the greatest quantity of magnetic flux in the Z direction.

When it is aimed at obtaining the greatest quantity of magnetic induction flux in the X direction, it can be acted on the power supplies of the upper coils 110A, 110B, 110C, 110D within a same power supply network (power supply of the field in the X direction). For example, coils 110C, 110D may be powered in phase opposition with respect to coils 110A, 110B. According to an example, coils 110A, 110B may be powered to generate an upward magnetic flux and coils 110C, 110D may be powered to generate a downward magnetic flux, which two fluxes may be combined in the X direction.

When it is aimed at obtaining the greatest quantity of magnetic induction flux in the Y direction, it can be acted on the power supplies of the lower coils 112A, 112B, 112C, 112D within a same power supply network (power supply of the field in the Y direction). For example, coils 112A, 112D may be powered in phase opposition with respect to coils 112B, 112C. For example, coils 112A, 112D may be powered to generate a downward magnetic flux and coils 112B, 112C may be powered to generate an upward magnetic flux, which two fluxes may be combined in the Y direction.

A disadvantage of this technique is that the power of all the coils cannot be assigned in a single direction, and that the magnetic field that could be generated by all the coils can thus not be maximized. If the problem is taken reversely, this technique requires having a lot of coils to generate a high magnetic field in a plurality of directions at the same time.

Another technique, aiming at increasing the magnetic flux in one direction, comprises using a system of relays coupled to the coils to reassign one or a plurality of coils of a power supply network on another direction. For example, all or part of coils 110A, 110B, 110C, 110D may be reassigned to a direction other than the X direction or all of part of coils 112A, 112D may be reassigned to a direction other than the Y direction.

A disadvantage of this other technique is on the one hand that the obtaining of a high magnetic flux along a direction is performed to the detriment of other directions, and that it thus does not enable to maximize the magnetic flux in a plurality of directions. Further, the changing from one configuration to another, by activating the concerned relays, may be a long operation, which may last for a few hundreds of milliseconds, for example from approximately 500 to approximately 1,000 milliseconds, and may induce wearings of the field generation system, particularly of the relays.

In certain applications of the present disclosure, the generated magnetic field is for example applied to for the testing of an integrated circuit wafer, where test probes are placed in electric contact with a component of the wafer, generally via electric contact pads. The electric measurements performed on the test probes, for example, of the electric resistance variations between test probes, according to the intensity and/or to the direction of the applied magnetic field, enable to characterize the wafer component.

For these applications, in particular when the application to the component of a magnetic field of high amplitude in a plurality of directions is desired, it may be necessary to carry out a plurality of tests by changing configuration for each test, for example, a first test configuration at high magnetic field in a first direction, and then a second test configuration at high magnetic field in a second direction. The multiplication of tests may also result in a premature wearing of the test probes and/or of the electric contact pads of the wafer by repeated contacts with the probes.

The inventors provide a system enabling to address the needs for improvement of magnetic field generation techniques, enabling to generate a magnetic field of high amplitude simultaneously in a plurality of directions, without for this to require too long operations, without it being necessary to multiply the coils and/or to use relays, and without risking a premature wearing of the system.

Embodiments of systems will be described hereafter. The described embodiments are non-limiting and various variants will occur to those skilled in the art based on the indications of the present disclosure.

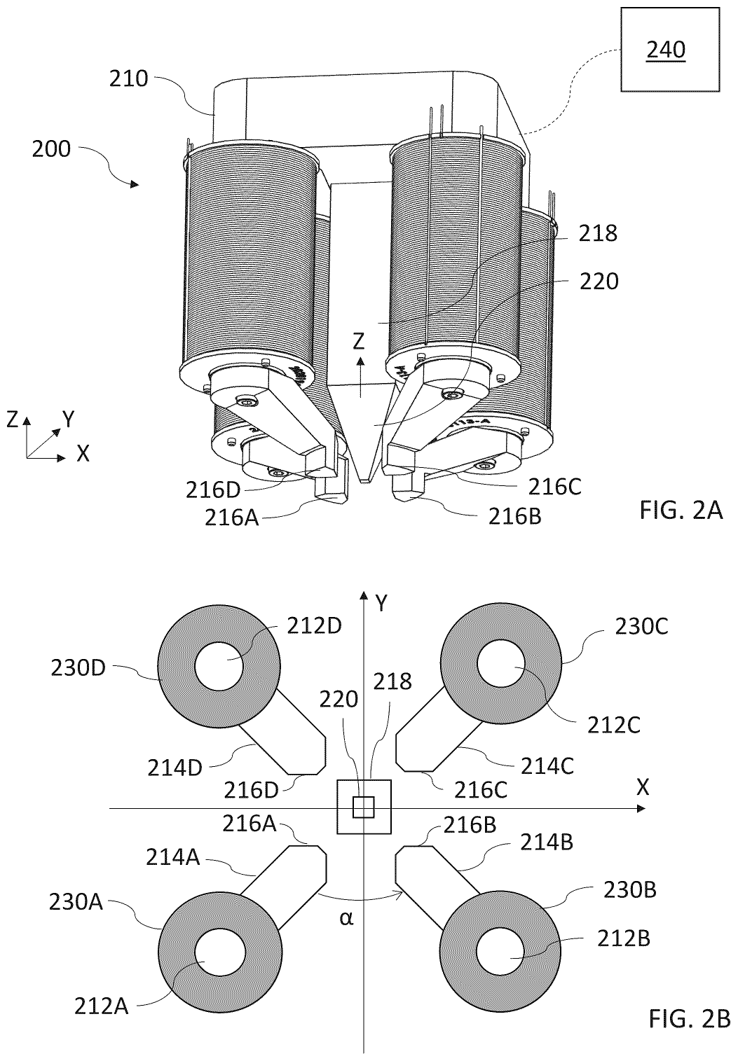

FIGS. 2A and 2B are respective perspective and transverse cross-section views of a magnetic field generation system 200 according to an embodiment.

The shown magnetic field generation system 200 comprises a magnetic circuit comprising a frame 210 of substantially square-shaped cross-section with rounded corners. Other frame shapes are possible. The axis of the frame (central axis) extends along vertical direction Z (orthogonal direction) and each side of the frame extends either a first horizontal direction X, or along a second horizontal direction Y perpendicular to the X direction. Vertical cylindrical bars 212A, 212B, 212C, 212D extend downwards from each corner of the frame, each bar being continued towards the central axis by a radial arm 214A, 214B, 214C, 214D substantially extending in a horizontal plane, or even slightly inclined with respect to a horizontal plane, and ending in a polar end 216A, 216B, 216C, 216D (planar pole). The planar poles have lower surfaces located in a same substantially horizontal plane XY.

Radial arms 214A, 214B, 214C, 214D and planar poles 216A, 216B, 216C, and 216D are oriented in the horizontal plane at approximately 45° with respect to the X direction and to the Y direction, as can be seen in FIG. 2B. Accordingly, two adjacent planar poles are oriented by an angle α equal to approximately 90° with respect to each other.

Further, a vertical arm 218 (central arm) having the shape of an elongated parallelepiped with a polar end 220 (central pole) having the shape of a truncated inverted pyramid extends vertically from the middle of frame 210 downwards. The central pole ends in a substantially horizontal surface (truncation of the truncated inverted pyramid).

The magnetic circuit (frame, bar, arm, poles) is made of a soft ferromagnetic material, for example, soft iron.

Each vertical bar is surrounded with a coil 230A, 230B, 230C, 230D. The coils may be identical.

The coils may be sized according to values of the magnetic field which is desired to be generated.

Preferably, the coils have outer diameters greater than 30 mm, for example in the range from 70 to 95 mm. Each coil may be formed by coiling of a copper conductive wire, for example made of copper, the number of turns of the conductive wire particularly depending on the wire diameter. Each coil may comprise several hundreds of turns of conductive wire, for example, from 100 to 5,000 turns. As an example, the coils have diameters of approximately 90 mm, and are formed with copper wires of 3.5 diameter and having a number of turns of approximately 900.

Each coil is connected to a power supply circuit which is specific thereto, not shown. Each power supply circuit enables to circulate a current having a direction and an intensity determined according to a desired magnetic field H and to the orientation in the plane of the planar pole associated with said coil.

According to an embodiment, an equivalent current Ieq is defined, for example, in the form of a vector \vec{I}eq, for the desired magnetic field B, for example also in the form of a vector \vec{B}, and the current to be circulated through each coil is determined according to the defined equivalent current to contribute to orienting the magnetic field, projected in a plane parallel to that of the planar poles, according to the desired direction(s). For example, the current to be circulated through each coil is determined from the equivalent current defined to maximize the magnetic field in one or a plurality of directions. Equivalent current Ieq may be determined by using an optimization or search algorithm, and/or an iterative algorithm. Preferably, the algorithm is adapted to determining an equivalent current Ieq for a desired magnetic field in the three directions.

For example, the algorithm is adapted to determining a dynamic, that is, time-variable, equivalent current vector \vec{I}eq(t) according to a dynamic magnetic field vector \vec{B}(t).

According to an example, the algorithm is adapted to compensating for the delay between the circulation of the different currents in the different coils and the magnetic field generated by these different currents, for example, the algorithm comprises one or a plurality of iterations.

An example of iterative algorithm is the following:
determination of a first equivalent current vector Ieq1(t) according to the desired magnetic field vector B(t), for example by using an optimization or search algorithm usual for those skilled in the art;
determination of the currents to be circulated through each of the coils according to the first equivalent current vector Ieq1(t), for example by means of the equations described hereafter;
measurement of the magnetic field vector B1(t) obtained by circulating the determined currents through the coils;
comparison of the obtained magnetic field vector B1(t) with the desired magnetic field B(t); then, if the measured magnetic field vector B1(t) is different from the desired magnetic field B(t), or is outside of a defined range around the desired magnetic field B(t),
determination of second (new) equivalent current vector Ieq2(t) according to the difference between the measured magnetic field vector B1(t) and the desired magnetic field vector B(t).

The steps of determination of the currents to be circulated, of measurement of the obtained magnetic field vector, and of determination of a new equivalent current vector are then repeated.

This succession of steps may be repeated until the measured magnetic field vector is equal to the desired magnetic field B(t) or within the range defined around the desired magnetic field B(t).

It should be noted that the equivalent current Ieq is to be considered as an intermediate parameterizing entity, and not as a current to be circulated as such through a circuit.

According to an example, the current to be circulated through each of the four coils can be determined by means of the four equations described in the following.

There is circulated through a first coil 230A associated with a first planar pole 216A a current of intensity I₁, with:

$${I}_{1} = {Ieq}_{X} + {Ieq}_{Y} + {Ieq}_{Z} ;$$

where Ieq_{X}, Ieq_{Y}, Ieq_{Z} are the vector components representing the equivalent current Ieq respectively along the first horizontal direction X, the second horizontal direction Y, and the vertical direction Z.

The first planar pole 216A is oriented towards the Z axis of the central pole towards the positive side of the X and Y directions, which explains the signs “+” in front of the X and Y components of intensity I. Further, since each planar pole is oriented at approximately 45° with respect to these directions in the plane, the fact of positively adding all the components of the equivalent current vector Ieq enables to maximize the magnetic flow generated by this first coil in each of the X and Y directions, but also in the Z direction as explained hereafter.

According to the same principle, and simultaneously, there is circulated through a second coil 230B associated with a second planar pole 216B oriented at approximately 90° in the plane with respect to the first planar pole 216A, a current of intensity I₂, with:

$${I}_{2} = - {Ieq}_{X} - {Ieq}_{Y} + {Ieq}_{Z}$$

The sign “−” in front of the X component of intensity I can be explained by the fact that second planar pole 216B is oriented towards the Z axis of the central pole towards the negative side of direction X, while it is oriented towards the positive side of direction Y, whereby the sign “+” in front of the Y component of intensity I.

According to the same principle, and simultaneously, there is circulated through a third coil 230C associated with a third planar pole 216C oriented at approximately 90° in the plane with respect to the second planar pole a current of intensity I₃, with:

$${I}_{3} = - {Ieq}_{X} - {Ieq}_{Y} + {Ieq}_{Z}$$

The signs “−” in front of the X and Y components of intensity I can be explained by the fact that third planar pole 216C is oriented towards the Z axis of the central pole in the negative direction of the X and Y directions.

According to the same principle, and simultaneously, there is circulated through a fourth coil 230D associated with a fourth planar pole 216D oriented at approximately 90° in the plane with respect to the third planar pole a current of intensity I₄, with:

$${I}_{4} = {Ieq}_{X} - {Ieq}_{Y} + {Ieq}_{Z}$$

The sign “−” in front of the Y component of intensity I can be explained by the fact that the fourth planar pole 216D is oriented towards the Z axis of the central pole towards the negative side of the Y direction, while it is oriented towards the positive side of the X direction, whereby the sign “+” in front of the X component of equivalent current Ieq.

The magnetic flux generated by each coil is directed towards central pole 220. It rises in the Z direction upwards (positive side of the Z direction) via vertical arm 218, which enables to have a maximized component of the magnetic field also in this direction, without it being necessary to arrange a coil around the central pole. In other words, the magnetic flux along the Z direction originates from the field lines attracted in central arm 218, having its material exhibiting a higher permeability than air. The fact of keeping the same sign (sign “+” in the given example) for term I_{z} in the equations of each of the coils aims at favoring this flux transfer, which enables to maximize the magnetic flux generated along the Z direction. As a variant, the same sign “−” could be introduced for term I_{z} in the equations of each of the coils.

This example enables to maximize the current generated by each of the four coils, simultaneously in each of the X, Y, Z directions. The equations providing the intensities of the coils, and particularly the signs in front of the equivalent current components, are selected so that each coil contributes to the same intensity, for example, to avoid for certain components of said intensity to cancel one another, and on the contrary to allow combining said components. Thus, the entire power of the four coils may be assigned at the same time in the three directions, without having to increase the number of coils and without it being necessary to switch from one configuration to another, for example, without it being necessary to use a relay.

A processing unit 240 may be coupled to the power supply circuit of each coil, and in certain cases to a magnetic field sensor (not shown), and be adapted to determining the components of the equivalent current vector Ieq according to the desired magnetic field H by means of an optimization and/or iterative algorithm such as that described above, and to determining the intensities to be circulated through each coil, for example, according to the above-described equations.

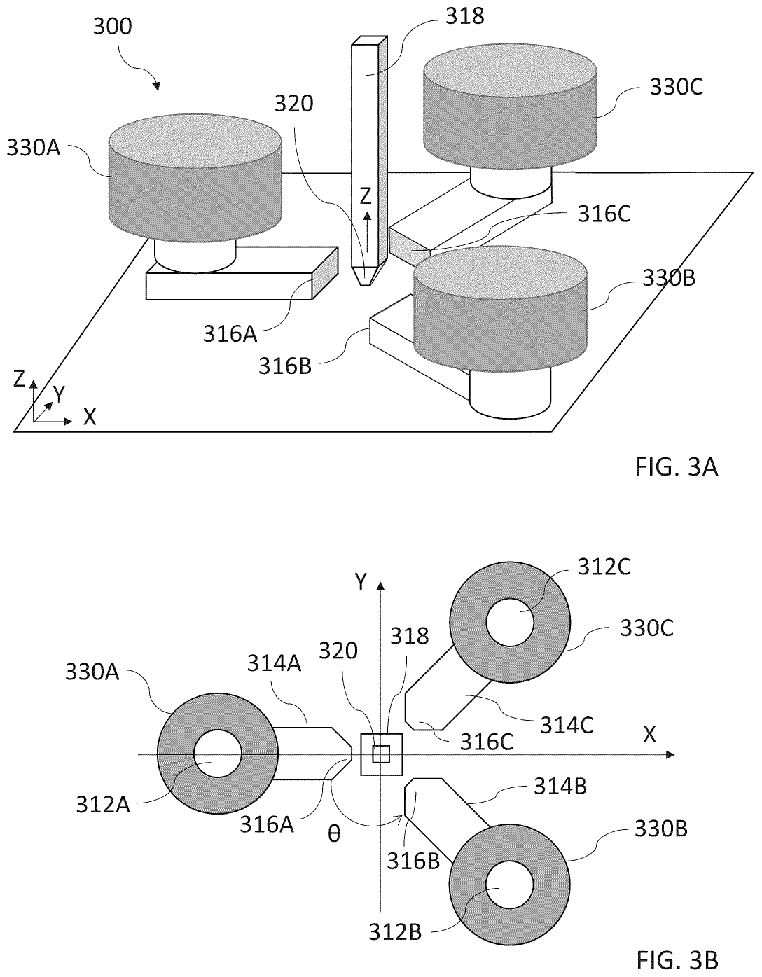

FIGS. 3A and 3B are respective perspective and transverse cross-section views of a magnetic field generation system 300 according to another embodiment, which differs from the embodiment of FIGS. 2A and 2B mainly in that there are three planar poles 316A, 316B, 316C and three coils 320A, 320B, 320C, one coil associated with one planar pole, instead of four planar poles and four coils.

Similarly to the system of FIGS. 2A and 2B, planar poles 316A, 316B, 316C are ends of radial arms 314A, 314B, 314C extending substantially in a horizontal plane, or even slightly inclined with respect to a horizontal plane, the radial arms being assembled with vertical cylindrical bars 312A, 312B, 312C. The planar poles have lower surfaces located in a same plane XY, said plane being substantially horizontal.

A first radial arm 314A and a first planar pole 316A are oriented in a first X direction of the plane. A second radial arm 314B and a second planar pole 316B are oriented by an angle θ in the plane with respect to the first planar pole. A third radial arm 314C and a third planar pole 316C are oriented by an angle θ in the plane with respect to the second planar pole. Angle θ is equal to approximately 120°.

Further, a vertical arm 318 (along the Z direction), or central arm, having the shape of an elongated parallelepiped with a polar end 320 (central pole) having the shape of a truncated inverted pyramid extends downwards. The central pole ends in a substantially horizontal surface (truncation of the truncated inverted pyramid).

The vertical bars and the vertical arm may be assembled with a frame, not shown, but which may be similar to the frame of FIGS. 2A and 2B, or have another shape, for example triangular, hexagonal, circuit, or any other adapted shape.

The planar poles are arranged symmetrically on the XY plane with respect to the axis of the central pole.

The magnetic circuit (frame, bar, arm, poles) is made of a soft ferromagnetic material, for example, soft iron.

Each vertical bar is surrounded with a coil 330A, 330B, 330C. The coils may be identical. The examples of coil sizing given in relation with FIGS. 2A and 2B may apply.

Similarly to the system of FIGS. 2A and 2B, each coil is connected to a power supply circuit which is specific thereto, not shown. Each circuit enables to circulate a current of direction and intensity determined according to a desired magnetic field H and to the orientation in the plane of the planar pole associated with said coil.

According to an embodiment similar to that described in relation with FIGS. 2A and 2B, an equivalent current Ieq is defined, for example in the form of a vector \vec{I}, for the desired magnetic field, and the current to be circulated through each coil is determined according to the defined equivalent current to contribute to orienting the magnetic field, projected in a plane parallel to that of the planar poles, in the desired direction(s). For example, the current to be circulated through each coil is determined to maximize the magnetic field in one or a plurality of directions.

According to an example, the current to be circulated through each of the three coils can be determined by means of the three equations described in the following. The principle is similar to the example described in relation with FIGS. 2A and 2B, but the equations are adapted to three coils instead of four.

There is circulated through a first coil 330A associated with the first planar pole 316A a current of intensity I₁, with:

$${I}_{1} = {Ieq}_{X} + {Ieq}_{Z}$$

where Ieq_{X}, Ieq_{Y}, Ieq_{Z} are the vector components representing the equivalent current Ieq respectively along the first horizontal direction X, the second direction Y perpendicular to the first direction in the plane, and the orthogonal direction Z.

The first planar pole 316A is oriented towards the Z axis of the central pole towards the positive side of the X direction, whereby the sign “+” in front of the X component of intensity I. Further, the first planar pole is perpendicular to direction Y, which explains that the Y component of intensity I does not appear in the equation.

According to the same principle, and simultaneously, there is circulated through a second coil 330B associated with the second planar pole 316B a current of intensity I₂, with:

$${I}_{2} = - \frac{1}{2} {Ieq}_{X} + \frac{\sqrt{3}}{2} {Ieq}_{Y} + {Ieq}_{Z}$$

The sign “−” in front of the X component of intensity I can be explained by the fact that second planar pole 316B is oriented towards the Z axis of the central pole towards the negative side of direction X, while it is oriented towards the positive side of direction Y, whereby the sign “+” in front of the Y component of intensity I.

Coefficients ½ and \sqrt{3}/2 are calculated according to the orientation of the second planar pole with respect to the X and Y directions.

According to the same principle, and simultaneously, there is circulated through a third coil 330C associated with the third planar pole 316C a current of intensity I₃, with:

$${I}_{3} = - \frac{1}{2} {Ieq}_{X} - \frac{\sqrt{3}}{2} {Ieq}_{Y} + {Ieq}_{Z}$$

The signs “−” in front of the X and Y components of intensity I can be explained by the fact that third planar pole 316C is oriented towards the Z axis of the central pole towards the negative side of the X and Y directions.

Coefficients ½ and \sqrt{3}/2 are calculated according to the orientation of the third planar pole with respect to the X and Y directions.

The magnetic flux generated by each coil is directed towards the central pole. It rises in the Z direction upwards (towards the positive side of the Z direction), which enables to have a maximized component of the magnetic field also in this direction, without it being necessary to have a coil around the central pole.

A processing unit (not shown) may be coupled to the power supply circuit of each coil, and in certain cases to a magnetic field sensor (not shown), and be adapted to determining the components of the equivalent current vector \vec{I}eq according to the desired magnetic field H by an optimization and/or iterative algorithm such as that described above, and to determining the intensities to be circulated through each coil, for example, according to the above-described equations.

This example enables to maximize the current generated by each of the three coils, simultaneously in each of the X, Y, Z directions. Indeed, the equations providing the intensities of the coils, and particularly the signs and coefficient in front of the equivalent current components, are selected so that each coil contributes to the same intensity, for example, to avoid for certain components of said intensity to cancel one another, and on the contrary to allow combining said components. Thus, the entire power of the three coils may be assigned at the same time in the three directions, without having to increase the number of coils and without it being necessary to switch from one configuration to another, for example, without it being necessary to use a relay.

The two described embodiments implement three or four planar poles. It can be seen that with at least three planar poles, it is possible to adjust the three components X, Y, Z of the magnetic field. Further, the embodiments enable to accurately adjust them.

Examples and equations have been given with three and four coils, but other examples and equations are possible, for example according to the number of coils, to the orientations of the planar poles associated with the coils with respect to the reference frame selected to define the components of the equivalent current, to the desired magnetic field, and/or to the directions in which the magnetic field is desired to be maximized.

Generally, the embodiments enable, by determining currents having an intensity and a direction specific to each coil, to maximize the components of the magnetic field in a plurality of directions at the same time. The intensities and directions of the current to be circulated through each coil may be determined to maximize the magnetic field in other directions than the X, Y, Z directions of the selected reference frame.

According to other embodiments, there may be more planar poles, or even two planar poles. In the case of two planar poles, it is possible to set two components of the magnetic field, a vertical component (Z) and a horizontal component (X or Y).

Although coils arranged around elements of the magnetic circuit have been described hereabove in a specific configuration in the two embodiments, other configurations are possible. As a variant, the coils may be replaced with coils located around the sides of the frame.

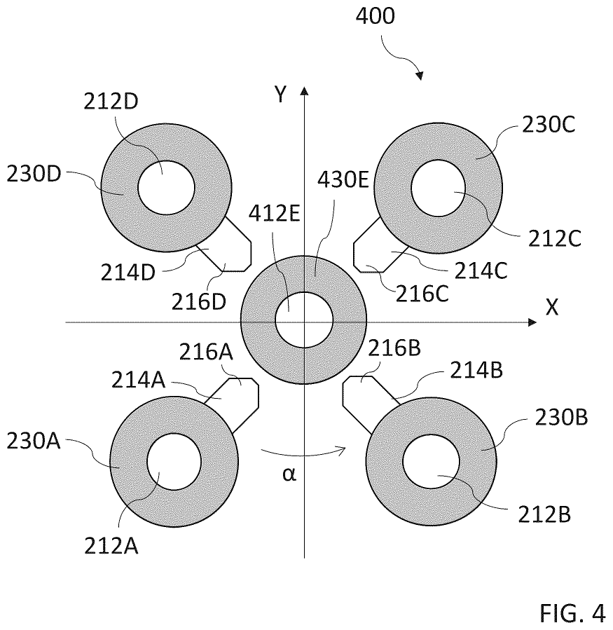

Further, no coil has been shown around the central arm in the two above embodiments. Indeed, generally, the embodiments may be implemented without it being necessary to associate a coil with the central pole to generate the Z component of the magnetic field, the latter being obtained by the magnetic fluxes generated in the X, Y directions of the plane and then rising (or falling) in the Z direction, in particular in the central pole. It is however possible to add at least one coil around the central arm if it is desired to maximize the magnetic flux in the Z direction, as shown in FIG. 4.

FIG. 4 is a simplified transverse cross-section of a magnetic field generation system 400 according to another embodiment, which differs from the embodiment of FIGS. 2A and 2B mainly in that central arm 412E has a cylindrical shape and is surrounded by a fifth coil 430E.

Similarly to the system of FIGS. 2A and 2B, each coil is connected to a power supply circuit which is specific thereto, not shown. Each circuit enables to circulate a current having a direction and an intensity determined according to a desired magnetic field H and to the orientation in the plane of the planar pole associated with said coil.

According to an embodiment similar to that described in relation with FIGS. 2A et 2B, an equivalent current Ieq is defined, for example, in the form of a vector \vec{I}eq, for the desired magnetic field, and the current to be circulated in each coil is determined according to the defined equivalent current to contribute to a desired magnetic field. For example, the current to be circulated through each coil is determined to maximize the magnetic field in one or a plurality of directions.

According to an example, the current to be circulated in each of the five coils can be determined by means of the five equations described in the following. The principle is similar to the example described in relation with FIGS. 2A and 2B, but the equations are adapted to the presence of a central coil, in addition to the four coils.

Similarly to FIGS. 2A and 2B, there are simultaneously circulated:
through a first coil 430A associated with a first planar pole 416A, a current of intensity I₁, with:

$${I}_{1} = {Ieq}_{X} + {Ieq}_{Y} + {Ieq}_{Z} ;$$

through a second coil 430B associated with a second planar pole 416B oriented at approximately 90° in the plane with respect to the first planar pole 416A, a current of intensity I₂, with:

$${I}_{2} = - {Ieq}_{X} + {Ieq}_{Y} + {Ieq}_{Z} ;$$

through a third coil 430C associated with a third planar pole 416C oriented at approximately 90° in the plane with respect to the second planar pole, a current of intensity I₃, with:

$${I}_{3} = - {Ieq}_{X} - {Ieq}_{Y} + {Ieq}_{Z} ;$$

through a fourth coil 430D associated with a fourth planar pole 416D oriented at approximately 90° in the plane with respect to the third planar pole, a current of intensity I₄, with:

$${I}_{4} = {Ieq}_{x} - {Ieq}_{y} + {Ieq}_{z}$$

Further, there is circulated through the fifth coil 430E a current of intensity: I_{S}=Ieq_{z}

Various embodiments and variants have been described. Those skilled in the art will understand that certain features of these various embodiments and variants may be combined, and other variants will occur to those skilled in the art. In particular, a vertical bar may have a shape other than cylindrical and/or may be surrounded by more than one coil. Further, a vertical arm may have a shape other than parallelepipedal with an end in the form of a truncated pyramid, for example, a cylindrical shape with an end in the form of a truncated cone.

Finally, the practical implementation of the described embodiments and variations is within the abilities of those skilled in the art based on the functional indications given hereabove.

1. Magnetic field generation system (200; 300; 400) comprising a magnetic circuit comprising:
a central pole (220; 320; 412E) arranged above a plane (XY), the axis of said central pole extending along an orthogonal direction (Z) substantially corresponding to the direction orthogonal to the plane;
at least two planar poles (216A, 216B, 216C, 216D; 316A, 316B, 316C) arranged symmetrically on the plane with respect to the axis of the central pole, each planar pole being supported by a portion of the magnetic circuit; and
at least two coils (230A, 230B, 230C, 230D; 330A, 330B, 330C), including at least one coil associated with each planar pole, each coil associated with a planar pole surrounding the magnetic circuit portion supporting said planar pole;
two coils associated with two different planar poles being adapted to being connected to two distinct power supply circuits; each power supply circuit being adapted to circulating through at least one coil to which it is connected a current having an intensity and a direction determined according to a desired magnetic field and to the orientation in the plane of the planar pole associated with said coil.

2. System (200; 300; 400) according to claim 1, further comprising a processing unit (240) adapted to determining the current to be circulated through each coil.

3. System (200; 300; 400) according to claim 2, wherein the processing unit (240) is adapted to determining an equivalent current (Ieq), for example in the form of an equivalent current vector, for the desired magnetic field, and to determining the current to be circulated through each coil according to the determined equivalent current and to the orientation in the plane of the planar pole associated with said coil.

4. System (300) according to any of claims 1 to 3, comprising three coils (330A, 330B, 330C) and three planar poles (316A, 316B, 316C) arranged symmetrically on the plane with respect to the axis of the central pole (320) and being oriented by a first angle (θ) of approximately 120° with respect to one another.

5. System (300) according to claim 4 as dependent on claim 3, wherein the currents to be circulated through the three coils (330A, 330B, 330C) are respectively:
$${I}_{1} = {Ieq}_{x} + {Ieq}_{z}$$
for a first coil (330A) associated with a first planar pole (316A) oriented towards the axis of the central pole (320) towards the positive side of a first direction (X) of the plane;
$${I}_{2} = - \frac{1}{2} {Ieq}_{x} + \frac{\sqrt{3}}{2} {Ieq}_{y} + {Ieq}_{z}$$
for a second coil (330B) associated with a second planar pole (316B) oriented by the first angle (θ) in the plane with respect to the first planar pole; and
$${I}_{3} = - \frac{1}{2} {Ieq}_{x} - \frac{\sqrt{3}}{2} {Ieq}_{y} + {Ieq}_{z}$$
for a third coil (330C) associated with a third planar pole (316C) oriented by the first angle (θ) in the plane with respect to the second planar pole; where Ieq_{X}, Ieq_{Y}, Ieq_{Z} are the vector components representing the equivalent current Ieq respectively along the first direction (X), the second direction (Y) perpendicular to the first direction in the plane, and the orthogonal direction (Z).

6. System (200; 400) according to any of claims 1 to 5, comprising four coils (230A, 230B, 230C, 230D) and four planar poles (216A, 216B, 216C, 216D) symmetrical with respect to two orthogonal planes containing the axis of the central pole (220), two adjacent planar poles being oriented by a second angle (α) of approximately 90° with respect to each other.

7. System (200) according to claim 6 as dependent on claim 3, wherein the currents to be circulated through the four coils (230A, 230B, 230C, 230D) are respectively:
$${I}_{1} = {Ieq}_{x} + {Ieq}_{y} + {Ieq}_{z}$$
for a first coil (230A) associated with a first planar pole (216A) oriented towards the axis of the central pole (220) at approximately 45° between first (X) and second (Y) directions orthogonal in the plane, towards the positive sides of said first and second directions;
$${I}_{2} = - {Ieq}_{x} + {Ieq}_{y} + {Ieq}_{z}$$
for a second coil (230B) associated with a second planar pole (216B) oriented by the second angle (α) in the plane with respect to the first planar pole;
$${I}_{3} = - {Ieq}_{x} - {Ieq}_{y} + {Ieq}_{z}$$
for a third coil (230C) associated with a third planar pole (216C) oriented by the second angle (α) in the plane with respect to the second planar pole; and
$${I}_{4} = {Ieq}_{x} - {Ieq}_{y} + {Ieq}_{z}$$
for a fourth coil (230D) associated with a fourth planar pole (216D) oriented by the second angle (α) in the plane with respect to the third planar pole; where Ieq_{X}, Ieq_{Y}, Ieq_{Z} are the vector components representing the equivalent current Ieq respectively along the first direction (X), the second direction (Y), and the orthogonal direction (Z).

8. System (600) according to any of claims 1 to 7 as dependent on claim 3, wherein the central pole (412E) is surrounded with a fifth coil (430E) adapted to being connected to a distinct power supply circuit of the coils associated with the planar poles and adapted to circulating through said fifth coil a current having an intensity and a direction determined according to the desired magnetic field and to the orientation of the central pole, for example, a current:
I₅=Ieq_{z};
where Ieq_{Z} is the vector component representing the equivalent current Ieq along the orthogonal direction (Z).

9. System (200; 300; 400) according to any of claims 1 to 8, wherein each pole corresponds to a first end of an arm (214A, 214B, 214C, 214D, 218; 314A, 314B, 314C, 318), the arms being coupled to a frame (210).

10. System (200; 300; 400) according to claim 9, wherein each arm (214A, 214B, 214C, 214D; 314A, 314B, 314C) associated with a planar pole (216A, 216B, 216C, 216D; 316A, 316B, 316C) extends substantially in a direction parallel to the plane, a second end of said arm being assembled to a bar (212A, 212B, 212C, 212D; 312A, 312B, 312C) running inside of the at least one coil associated with said planar pole, each bar substantially extending in the orthogonal direction (Z).

11. System according to claim 9 or 10, wherein the arm associated with the central pole is assembled with a horizontal rod coupled to two opposite sides of the frame.

12. System according to any of claims 1 to 11, wherein the coils have outer diameters greater than 70 mm, or even greater than 80 mm, for example, greater than or equal to 90 mm.

13. Magnetic field generation method implementing a system (200; 300; 400) comprising a magnetic circuit comprising:
a central pole (220; 320; 412E) arranged above a plane (XY), the axis of said central pole extending along an orthogonal direction (Z) substantially corresponding to the direction to orthogonal the plane;
at least two planar poles (216A, 216B, 216C, 216D; 316A, 316B, 316C) arranged symmetrically on the plane with respect to the axis of the central pole, each planar pole being supported by a portion of the magnetic circuit; and
at least two coils (230A, 230B, 230C, 230D; 330A, 330B, 330C), including at least one coil associated with each planar pole, each coil associated with a planar pole surrounding the magnetic circuit portion supporting said planar pole; two coils associated with two different planar poles being connected to two distinct power supply circuits;
the method comprising:
circulating, through at least one coil connected to each power supply circuit, a current having an intensity and a direction determined according to a desired magnetic field and to the orientation in the plane of the planar pole associated with said coil.

14. Method according to claim 13, comprising:
determining an equivalent current, for example in the form of an equivalent current vector, according to the desired magnetic field; and
determining the current to be circulated through each coil according to the determined equivalent current and to the orientation in the plane of the planar pole associated with said coil.

15. Method according to claim 14, further comprising:
measuring the magnetic field obtained when the determined current flows through each coil;
comparing the measured magnetic field with the desired magnetic field; and, if the difference is greater than a defined threshold,
determining a second equivalent current according to the difference between the measured magnetic field and the desired magnetic field;
determining the current to be circulated through each coil according to the determined second equivalent current and to the orientation in the plane of the planar pole associated with said coil; and
repeating at least the magnetic field measurement and comparison steps, and, for example, also repeating the steps of determination of the second equivalent current and of the current to be circulated.

16. Method according to claim 14 or 15, wherein the system comprises three coils (330A, 330B, 330C) and three planar poles (316A, 316B, 316C) arranged symmetrically on the plane with respect to the axis of the central pole (320) and being oriented by a first angle (θ) of approximately 120° with respect to one another; the method comprising:
circulating through a first coil (330A) associated with a first planar pole (316A) oriented towards the axis of the central pole (Z) towards the positive side of a first direction (X) of the plane a current of intensity:
$${I}_{1} = {Ieq}_{x} + {Ieq}_{z} ;$$
circulating through a second coil (330B) associated with a second planar pole (316B) oriented by the first angle (θ) in the plane with respect to the first planar pole a current of intensity:
$${I}_{2} = - \frac{1}{2} {Ieq}_{x} + \frac{\sqrt{3}}{2} {Ieq}_{y} + {Ieq}_{z} ;$$
and
circulating through a third coil (330C) associated with a third planar pole (316C) oriented by the first angle (θ) in the plane with respect to the second planar pole a current of intensity:
$${I}_{3} = - \frac{1}{2} {Ieq}_{x} - \frac{\sqrt{3}}{2} {Ieq}_{y} + {Ieq}_{z} ;$$
where Ieq_{X}, Ieq_{Y}, Ieq_{Z} are the vector components representing the equivalent current Ieq respectively along the first direction (X), the second direction (Y) perpendicular to the first direction in the plane (XY), and the orthogonal direction (Z).

17. Method according to claim 16, comprising four coils (230A, 230B, 230C, 230D) and four planar poles (216A, 216B, 216C, 216D) symmetrical with respect to two orthogonal planes containing the axis of the central pole (220), two adjacent planar poles being oriented substantially by a second angle (α) of approximately 90° with respect to each other;
the method comprising:
circulating through a first coil (230A) associated with a first planar pole (216A) oriented towards the axis of the central pole (220) at approximately 45° between first (X) and second (Y) orthogonal directions in the plane, towards the positive sides of said first and second direction, a current of intensity:
$${I}_{1} = {Ieq}_{x} + {Ieq}_{y} + {Ieq}_{z} ;$$
circulating through a second coil (230B) associated with a second planar pole (216B) oriented by the second angle (α) in the plane with respect to the first planar pole a current of intensity:
$${I}_{2} = - {Ieq}_{x} + {Ieq}_{y} + {Ieq}_{z} ;$$
circulating through a third coil (230C) associated with a third planar pole (216C) oriented by the second angle (α) in the plane with respect to the second planar pole a current of intensity:
$${I}_{3} = - {Ieq}_{x} - {Ieq}_{y} + {Ieq}_{z} ;$$
circulating through a fourth coil (230D) associated with a fourth planar pole (216D) oriented by the second angle (α) in the plane with respect to the third planar pole a current of intensity:
$${I}_{4} = {Ieq}_{x} - {Ieq}_{y} + {Ieq}_{z} ;$$
where Ieq_{X}, Ieq_{Y}, Ieq_{Z} are the vector components representing the equivalent current Ieq respectively along the first direction (X), the second direction (Y), and the orthogonal direction (Z).

18. System (300) according to any of claims 1 to 12 in combination with claim 3, or method according to any of claims 13 to 17 in combination with claim 14, wherein the determined equivalent current vector and the desired magnetic field are dynamic.
